(19) United States
(12) Patent Application Publication
(10) Pub. No.: US 2018/0323243 A1
(43) Pub. Date: Nov. 8, 2018

(54) ARRAY SUBSTRATE, IMAGE COLLECTION METHOD AND DISPLAY DEVICE

(71) Applicant: BOE TECHNOLOGY GROUP CO., LTD., Beijing (CN)

(72) Inventors: Pengpeng WANG, Beijing (CN); Xue DONG, Beijing (CN); Haisheng WANG, Beijing (CN); Xiaoliang DING, Beijing (CN); Yingming LIU, Beijing (CN); Chih Jen CHENG, Beijing (CN); Yanling HAN, Beijing (CN); Wei LIU, Beijing (CN); Xueyou CAO, Beijing (CN); Ping ZHANG, Beijing (CN)

(21) Appl. No.: 15/776,421

(22) PCT Filed: Nov. 16, 2017
(86) PCT No.: PCT/CN2017/111318

§ 371 Date: May 16, 2018

(30) Foreign Application Priority Data
May 2, 2017 (CN) 201710300744.9

(51) Int. Cl. H01L 27/32; G09G 3/3216; G06K 7/14; G06K 7/10

(52) U.S. Cl. CPC H01L 27/3227; H01L 27/3276; H01L 27/3288; G06K 9/0004; G06K 7/1413; G06K 7/1417; G06K 7/10722; G09G 3/3216

(57) ABSTRACT

An array substrate includes: a base substrate; a plurality of first electrodes disposed on the base substrate; a plurality of second electrodes disposed above the plurality of first electrodes, wherein orthographic projections of the plurality of second electrodes on the base substrate and orthographic projections of the plurality of first electrodes on the base substrate are intersectingly arranged; a plurality of pixel units located in overlapping areas of the orthographic projections of the plurality of second electrodes on the base substrate and the orthographic projections of the plurality of first electrodes on the base substrate, respectively; and a plurality of photosensitive units disposed at gaps between adjacent two of the plurality of pixel units, respectively, for receiving light signals emitted by the plurality of pixel units and reflected by the object to be detected and transforming the received light signals into electric signals.

### CROSS REFERENCE

The present disclosure is based upon International Application No. PCT/CN2017/111318, filed on Nov. 16, 2017, which claims priority to Chinese Patent Application No. 201710300744.9, filed with the State Intellectual Property Office of P.R.C. on May 2, 2017, and the entire contents thereof are incorporated herein by reference.

### TECHNICAL FIELD

The present disclosure relates to the technical field of display, and in particular, to an array substrate, an image collection method, and a display device.

### BACKGROUND

Image collection has been closely related to people's lives, such as the currently popular barcode recognition, two-dimensional code recognition, fingerprint recognition or more complex image collection. How to integrate image collection in the display area of the display screen has become a focus of attention in the field of screen integration technology.

OLEDs (Organic Light-Emitting Diodes) are considered to be the most likely substitutions for liquid crystal displays due to their advantages such as self-luminance, high contrast, wide color gamut, and low power consumption. According to driving modes, the OLED can be classified into PMOLED (Passive Matrix Driving OLED) and AMOLED (Active Matrix Driving OLED).

It should be noted that the information disclosed in the foregoing background section is only for enhancement of understanding of the background of the disclosure and therefore may include information that does not constitute prior art that is already known to those of ordinary skill in the art.

### SUMMARY

The present disclosure provides an array substrate, an image collection method, and a display device.

According to an aspect of the present disclosure, there is provided an array substrate comprising:

a base substrate;

a plurality of first electrodes disposed on the base substrate;

a plurality of second electrodes disposed above the plurality of first electrodes, wherein orthographic projections of the plurality of second electrodes on the base substrate and orthographic projections of the plurality of first electrodes on the base substrate are arranged to intersect each other;

a plurality of pixel units located in overlapping areas of the orthographic projections of the plurality of second electrodes on the base substrate and the orthographic projections of the plurality of first electrodes on the base substrate, respectively; and

a plurality of photosensitive units disposed at gaps between adjacent two of the plurality of pixel units, respectively.

In an exemplary embodiment of the present disclosure, the plurality of photosensitive units are located between the base substrate and the plurality of first electrodes.

In an exemplary embodiment of the present disclosure, the plurality of photosensitive units are located in areas not covered by the first electrodes and not covered by the second electrodes.

In an exemplary embodiment of the present disclosure, the plurality of pixel units are OLED pixel units.

In an exemplary embodiment of the present disclosure, the array substrate further comprises:

a photosensitive detection circuit disposed on the base substrate and configured to collect electrical signals output by the plurality of photosensitive units.

In an exemplary embodiment of the present disclosure, the photosensitive detection circuit comprises an active detection circuit.

In an exemplary embodiment of the present disclosure, the array substrate further comprises:

a driving unit configured to drive the plurality of pixel units by way of progressive scanning.

In an exemplary embodiment of the present disclosure, the plurality of photosensitive units are PIN photosensitive elements or PN junction photosensitive elements.

According to an aspect of the present disclosure, there is provided an image collection method applied to the array substrate according to any one of the above items, comprising:

spatially modulating optical signals emitted by the plurality of pixel units depending on a plurality of frames;

collecting electrical signals output by the plurality of photosensitive units by way of optical amplitude modulation; and

obtaining detection result of the object to be detected depending on the electrical signals collected in the perspective preset frames.

In an exemplary embodiment of the present disclosure, the spatially modulating optical signals comprises:

spatially modulating the optical signals by the plurality of pixel units in a manner of being alternately bright and dark.

According to an aspect of the present disclosure, there is provided a display device comprising the array substrate according to any one of the above items.

It is to be understood that both the foregoing general description and the following detailed description are exemplary and explanatory only and are not restrictive of the disclosure.

This section provides a general description for various implementations or examples of the technology as described in the present disclosure, which, however, is not a comprehensive disclosure for the entire protection scope or all technical features of the technology of the present disclosure.

### BRIEF DESCRIPTION OF THE DRAWINGS

The accompanying drawings, which herein are incorporated in and constitute a part of this specification, illustrate embodiments consistent with the present disclosure, and serve to explain the principles of the disclosure together with the specification. Obviously, the drawings in the following description are merely some of the embodiments of the present disclosure. Those skilled in the art can also obtain other drawings based on these drawings without any creative work.

FIG. 1 shows a schematic structural view of an array substrate adopting AMOLED integrated image collection technology in an implementation.

FIG. 2 shows a schematic structural view of an array substrate adopting PMOLED integrated image collection technology according to an exemplary embodiment of the present disclosure.

FIG. 3 shows a schematic structural view of an array substrate adopting PMOLED integrated image collection technology according to another exemplary embodiment of the present disclosure.

FIG. 4 schematically shows a top view of an array substrate adopting PMOLED integrated image collection technology according to an exemplary embodiment of the present disclosure.

FIG. 5 schematically shows a first top view of dot like stripe image collection according to an exemplary embodiment of the present disclosure.

FIG. 6 schematically shows a second top view of dot like stripe image collection according to an exemplary embodiment of the present disclosure.

FIG. 7 schematically shows a view of detection principle of a photosensitive sensor adopting optical amplitude modulation technology according to an exemplary embodiment of the present disclosure.

FIG. 8 schematically illustrates an active detection circuit for collecting a signal output by a photosensitive sensor according to an exemplary embodiment of the present disclosure.

FIG. 9 schematically shows a flowchart of an image collection method according to an exemplary embodiment of the present disclosure.

### DETAILED DESCRIPTION

Exemplary embodiments will now be described more fully with reference to the accompanying drawings. However, the exemplary embodiments can be implemented in various ways and should not be construed as limited to the examples set forth herein. Rather, these embodiments are provided to render the present disclosure to be more full and complete, and fully convey the concept of the exemplary embodiments to those skilled in the art. The described features, structures, or characteristics may be combined in any suitable manner in one or more embodiments. In the following description, many specific details are provided to give a full understanding of the embodiments of the present disclosure. However, those skilled in the art will recognize that the technical solutions of the present disclosure may be practiced with omitting one or more of the specific details, or may be employed by other methods, components, devices, steps, etc. In other instances, well-known technologies are not shown or described in detail to avoid obscuring aspects of the present disclosure.

Moreover, the drawings are merely schematic illustration of the present disclosure and are not necessarily drawn to scale. The same reference numerals in the drawings denote the same or similar parts, and their repeated description will be omitted. Some of the block diagrams shown in the figures are functional entities and do not necessarily have to correspond to physically or logically independent entities. These functional entities may be implemented in software, or implemented in one or more hardware modules or integrated circuits, or implemented in different network and/or processor devices and/or microcontroller devices.

The principle of integrating image collection in the display area of the display screen is that the wavelengths of the visible light reflected by the objects of different colors are different, the black object absorbs visible light of various wavelengths, and the white object reflects visible light of various wavelengths, and therefore, the light source generated from the display area of the display screen is projected onto a bar code or a two-dimensional code, and then the bar code or the two-dimensional code can be read out by using the characteristics of the photosensitive elements on the display screen having different reactions (output currents) for different wavelengths of light waves.

If the optical image collection function can be integrated in OLED displays, the value of OLED displays will be further enhanced. The difficulty of integrating optical image collection in the OLED display screen lies in that, on the one hand, the optical signals in the display area are often very weak and are easily interfered by the ambient light, while it is difficult for the current optical sensors to collect such weak signals due to the limitation to the area of the sensors; on the other hand, due to the presence of the pixel circuit on the AMOLED backplane, it is difficult to provide a space for the optical sensors and the sensor detection circuit, resulting in extremely limited detection of the optical signals.

Therefore, there is a need to provide an array substrate and a display device that can solve one or more of the above problems.

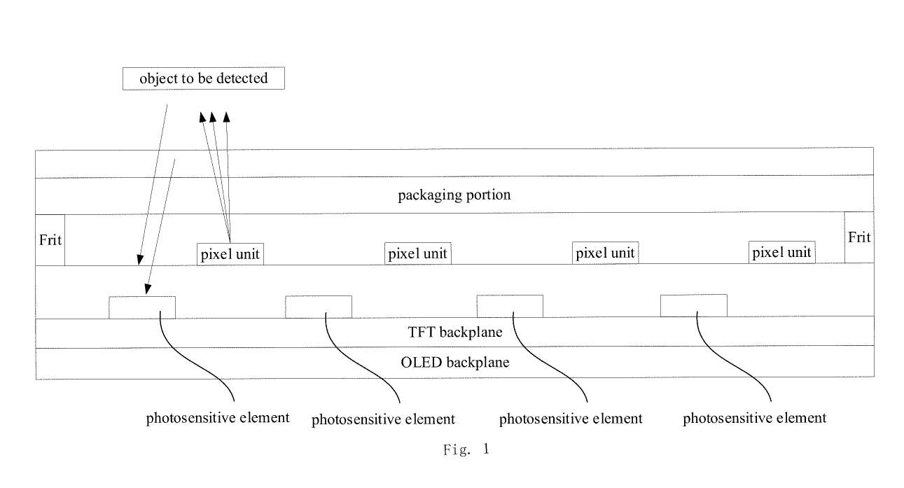

In an AMOLED integrated image collection technology solution, referring to FIG. 1, optical sensors, i.e., photosensitive elements, are disposed on a TFT backplane, and a detection circuit for detecting output signals of the optical sensors also have to be disposed on the TFT backplane. The photosensitive elements receive optical signals emitted by the pixel units and reflected by the object to be detected. In this technical solution, on the one hand, since the luminous pixels of AMOLED adopt an active driving mode and a pixel compensation circuit has to be provided on the TFT backplane and may occupy a large space on the TFT backplane, it is difficult to provide enough space for placing the photosensitive elements and the photosensitive element detection circuit; on the other hand, since the driving mode for AMOLED is relatively complicated, and GOA (Gate Driver on Array), i.e., a line driving mode of the array substrate, is often adopted for driving, when it is necessary to improve the pixel driving, it is difficult for GOA to correspond to a complicated or a specific driving mode, making it further difficult to improve the image collection effect.

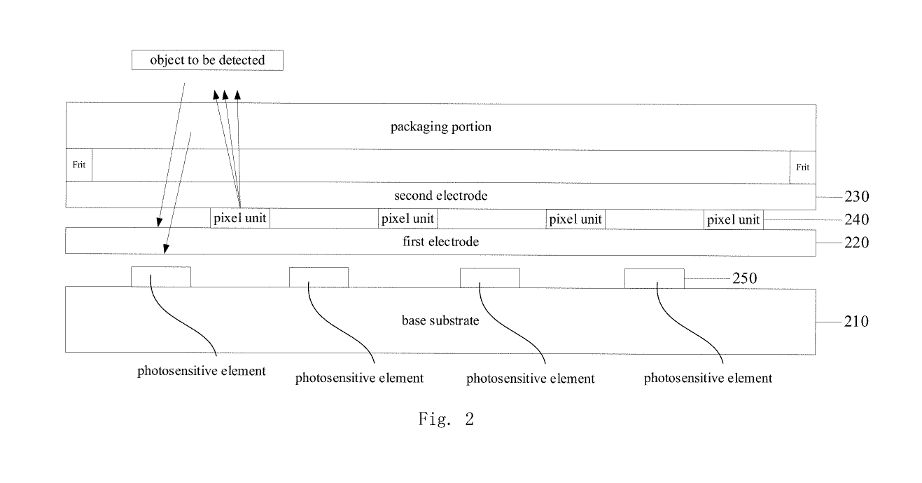

Based on the above, in the present exemplary embodiment, an array substrate is first provided. As shown in FIG. 2, the array substrate may comprise a base substrate 210; a plurality of first electrodes 220 disposed on the base substrate 210; a plurality of second electrodes 230 disposed on the base substrate 210, wherein the projections of the plurality of second electrodes 230 on the base substrate 210 and the projections of the plurality of first electrodes 220 on the base substrate are arranged to intersect each other; a plurality of pixel units 240 located between areas of the first electrodes 220 and the second electrodes 230 facing each other; and a plurality of photosensitive units 250 disposed at the gaps between the pixel units 240 for receiving the light signals emitted by the plurality of pixel units 240 and reflected by the object to be detected and convert the received light signals into electrical signals.

In the array substrate according to the present exemplary embodiment, on the one hand, using a PMOLED pixel structure, a plurality of photosensitive units are disposed at the gaps of the pixel units, and since the PMOLED pixel structure does not have to provide a pixel circuit on the array substrate, enough space can be provided for the photosensitive units and the photosensitive unit detection circuit; on the other hand, the light signals emitted from the pixel units and reflected by the object to be detected are received by the photosensitive units, and since the driving manner of the PMOLED is a manner of progressive driving, the interference problem caused by the luminance of other rows of pixels illuminating the photosensitive elements can be relieved, the ambient light interference is reduced, the signal-to-noise ratio is improved, and thus weak optical signals can be collected.

Next, the array substrate in this exemplary embodiment will be described in detail.

In the present exemplary embodiment, referring to FIG. 2, the plurality of photosensitive units 250 may be located between the base substrate 210 and the first electrodes 220. Specifically, the photosensitive elements may be located at the gap areas of the pixel units 240. In addition, the photosensitive elements may also be located directly below the first electrodes 220 and on the gaps of the pixel units 240, and may also be located at other positions at the gaps of the pixel units 240, which is also within the scope of the present disclosure. In the present exemplary embodiment, the first electrode may be an ITO anode, i.e., an indium tin oxide anode, and the second electrode may be a metal cathode.

In the present exemplary embodiment, the photosensitive unit 250 may be a PIN photosensitive element or a PN junction photosensitive element. When detection of an object to be detected such as a two-dimensional code or a bar code is made, a plurality of selected pixel units 240 driven by the driving circuit emit light. When the light emitted from the pixel units 240 illuminates the object to be detected, part of the light is reflected to the PIN photosensitive sensors or the PN junction photosensitive sensors which receive the reflected light signals and convert the received light signals into electrical signals.

It should be noted that in the present exemplary embodiment, the object to be detected may be a two-dimensional code or a bar code, but the object to be detected in the exemplary embodiment of the present disclosure is not limited thereto. For example, the object to be detected may also be a fingerprint, an iris, or the like, which is also within the scope of the present disclosure.

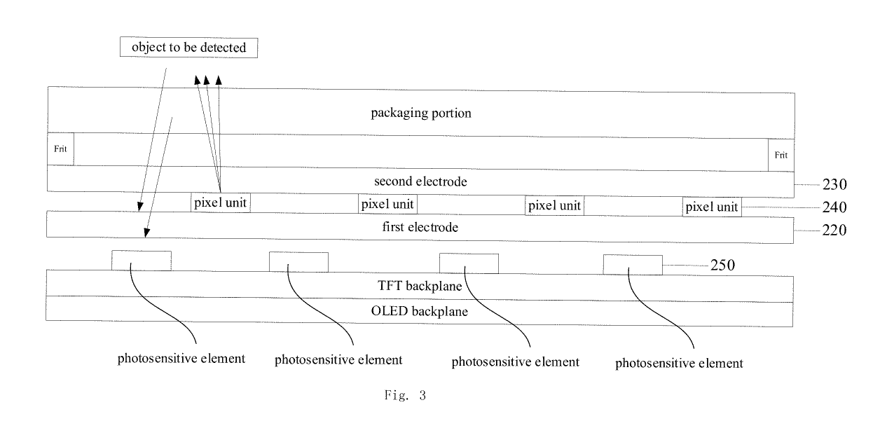

In the present exemplary embodiment, referring to FIG. 3, the base substrate 210 may comprise an OLED backplane and a TFT backplane. The TFT back plate and the photosensitive elements may be fabricated first, and then a PMOLED device may be fabricated over the photosensitive elements. For example, first electrodes, OLED pixels, and second electrodes may be formed over the photosensitive elements. Alternatively, it is also possible to prepare the photosensitive elements before fabricating the TFT backplane, which is also within the scope of the disclosure. Since the PMOLED pixel units do not need a pixel compensation circuit, a photosensitive detection circuit can be fabricated on the TFT backplane. Therefore, in the present exemplary embodiment, the array substrate may further comprise a photosensitive detection circuit disposed on the base substrate 210 for collecting electrical signals output by the plurality of photosensitive units 250.

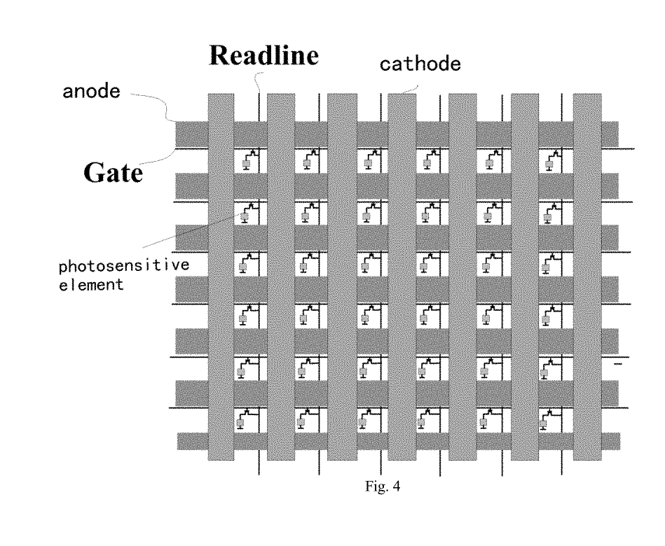

Further, FIG. 4 shows an arrangement of photosensitive elements in the gap areas of the pixel units. In FIG. 4, the positions where the cathode and the anode intersect with each other are pixel unit areas. After signals are applied to the cathode and the anode, the pixel units at the positions where the cathode and the anode intersect with each other emit corresponding light signals according to amplitudes of the signals. Since PMOLED only has one row of pixels to emit light at one same time, it will be more accurate than the case where the entire frame of AMOLED emits light, because if the entire frame is lit, the photosensitive sensors located in the first row will receive, in addition to the light emitted by the first row of pixels and reflected, the light from other rows of pixels and reflected, thereby resulting in blurring of the finally collected image of the object to be detected. At the same time, since the stripe structure of the cathode and the anode facilitates driving of the PMOLED, the leads can directly enter the driving IC. As long as appropriate signals are applied to the cathode and the anode, a more complex spatial modulation detection of the light pattern can be realized.

In addition, in the present exemplary embodiment, since PMOLED is used as the backlight for the photosensitive elements, the backlight can be patterned. By way of spatial modulation of the pixel units, for example, by making the pixel units show a specific pattern, i.e., a preset frame, for example, alternating bright and dark strips or dots, the optical signals are spatially modulated, thereby reducing ambient light interference and improving the signal-to-noise ratio. Accordingly, the array substrate may further comprise: a modulation unit configured to spatially modulate the optical signals depending on a plurality of preset frames; and a processing unit configured to obtain the detection result of the object to be detected depending on the electrical signals output by the photosensitive units in the perspective preset frames.

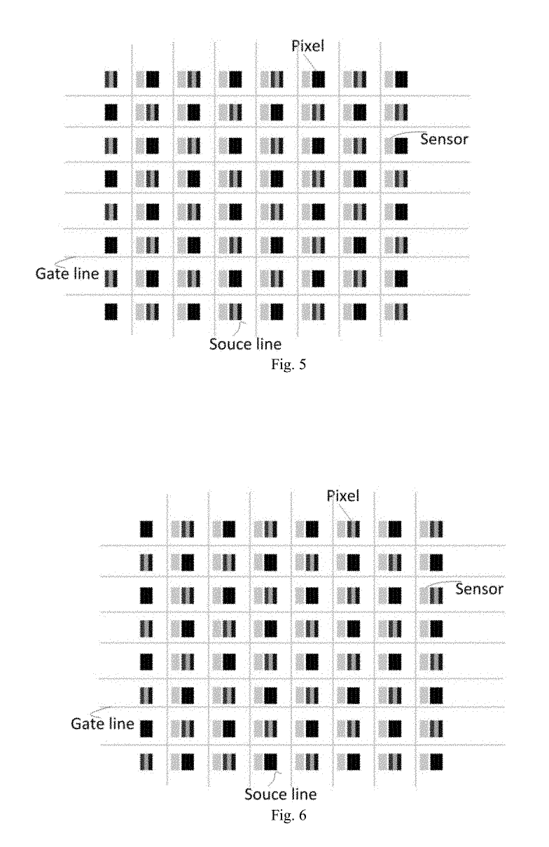

Specifically, in the present exemplary embodiment, the pixel units may be divided into several individually controllable “sub-pixels”, and a specific pattern may be displayed when a different number of sub-pixels in the pixel units are switched on. FIG. 5 and FIG. 6 are schematic views for spatially modulating optical signals by displaying a specific pattern, i.e., a preset frame, by pixel units. FIG. 5 is a first top view of a light source in shape of dot like stripe for optical spatial modulation of PMOLED in an exemplary embodiment. As can be seen from FIG. 5, each unit is divided into two parts, i.e., two blocks. The right block is a pixel unit, i.e., an OLED light emitting pixel. The left block is a photosensitive element located obliquely above the OLED light emitting pixel. As can be seen from FIG. 5, the OLED around the photosensitive elements shown in the figure is all black, which can minimize the interference of other surrounding stray light reflections.

FIG. 6 is a second top view of a light source in shape of dot like stripe for optical spatial modulation of PMOLED in the present exemplary embodiment. FIG. 5 and FIG. 6 are views of two preset frames when performing optical signal detection, and have similar structures except that at the positions where black dots are in FIG. 6 are the white dots in FIG. 5. Combining the signals of the photosensitive elements collected in FIG. 5 and the signals of the photosensitive elements collected in FIG. 6, the signal data of all the photosensitive elements in the entire screen can be collected, i.e., the entire optical image of the object to be detected can be collected. Therefore, after the data collected in FIG. 5 and FIG. 6 can be analyzed and processed, a clear image can be finally obtained.

In the image collection process of FIG. 5 and FIG. 6, two frames of data are collected under the dot like stripe backlight as shown in FIG. 5 and FIG. 6, respectively, and then the collected two frames of image signals are analyzed and processed, for example, for each frame, only the signals from the photosensitive elements nearest to the luminous OLED are taken, the noise caused by the surrounding light source may be eliminated, thereby improving the signal-to-noise ratio and achieving image refinement.

It should be noted that in the present exemplary embodiment, when collecting optical image signals, PMOLED may synchronously display corresponding pictures. Accordingly, the picture display of PMOLED is required to meet a certain timing relationship with the image detection. For example, the picture display and the image detection may be made in an alternating manner.

Further, in this exemplary embodiment, in order to improve the signal-to-noise ratio, the optical image signals may be adjusted by causing the OLED backlight to display a specific pattern, and therefore, the optical signals may be spatially modulated by a plurality of pixel units in a manner of being alternately bright and dark. In this exemplary embodiment, the manner of being alternately bright and dark may comprise alternating bright and dark stripes or dots. The exemplary embodiments of the present disclosure are not limited thereto. The OLED backlight pattern may adopt more complicated shapes of pattern. For example, also a variety of bar shapes, dot center shapes, and the like may be adopted. Therefore, the shape of the backlight pattern displayed by the pixel units in the exemplary embodiment of the present disclosure is not particularly limited.

In addition, in the present exemplary embodiment, it is not to say that only two frames are possible to use to compose the entire screen. Under the premise of complicated pattern shapes, three frames or even more frames of pictures may be similarly used to finally compose the entire screen, thereby obtaining more effective fingerprint data and improving the signal-to-noise ratio of the final image.

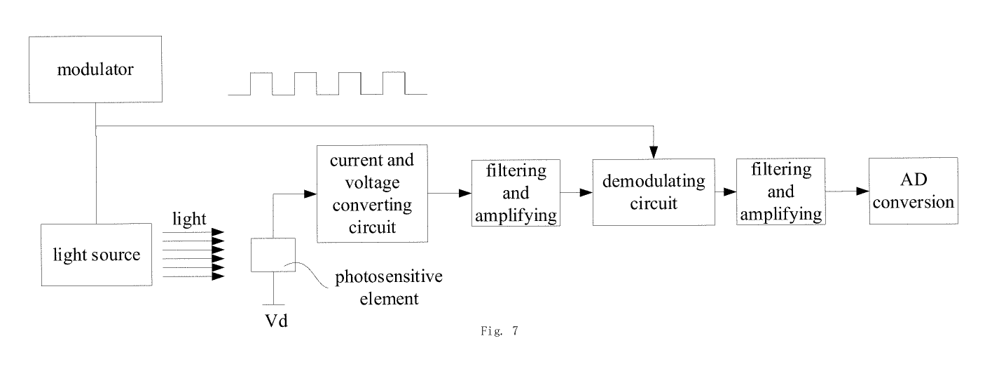

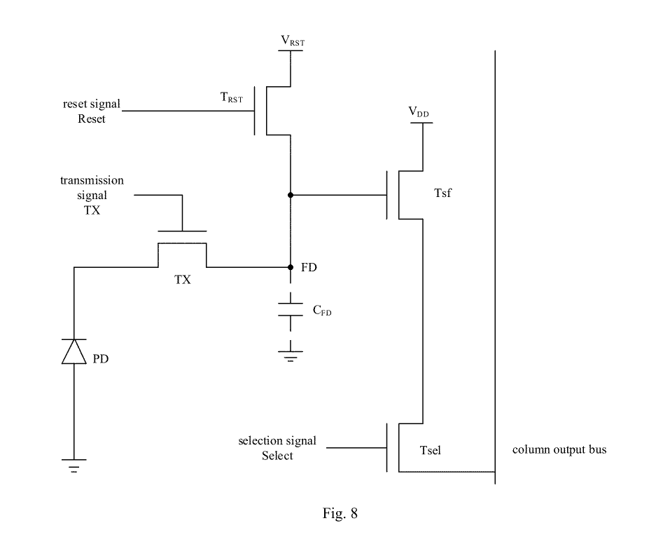

Further, in the present exemplary embodiment, an optical amplitude modulation technique may also be used when detecting the electrical signal output by the photosensitive elements. Since the PMOLED is directly driven by the driver IC, the driving timing is simpler than that of the AMOLED. Referring to FIG. 7, when performing image collection on the object to be detected, a modulator generates a square wave signal with a fixed frequency, which signal is divided into two channels. One channel is used to drive pixel units to emit light to generate modulated optical signals. Another channel is for demodulation of the collected image signals. When performing image collection on the object to be detected, the modulated light signals illuminate the object to be detected and are reflected. The reflected modulated light illuminates the photosensitive units to generate photocurrents. The photocurrents first enter a voltage conversion circuit to convert the photocurrent signals into photovoltage signals then pass through a first filtering and amplifying circuit and enter the demodulation circuit for demodulation. In demodulation of the collected image signals, another signal output from the modulator may be used, which has been demodulated by the demodulation circuit and finally passed through a second filtering circuit with a low-pass filter for low-pass filtering, and then an extracted analog signal containing the image information is obtained. After entering the analog-digital conversion circuit, the analog signal is converted into a digital signal which is finally output to the processing unit for subsequent processing to obtain the final image information. The use of modulated light can resist the interference of external light, environmental noise, and electrical noise to improve the signal-to-noise ratio.

In addition, in collection of the electrical signals output by the photosensitive sensors, an active detection circuit structure may also be used for the collection. Since the OLED does not require the use of pixel circuits, there will be sufficient space for the detection circuit on the TFT backplane. A 4T-APS (four-transistor active pixel sensor) active detection circuit is shown in FIG. 8. The 4T-APS active detection circuit may comprise: a reset switch transistor TRST, a photodiode PD, a transmission gate switch transistor TX, and a source follower transistor Tsf for reading a photoelectric signal stored in a parasitic node FD, and a selection switch transistor Tsel. Here the control terminal of the reset switch transistor TRST is configured to receive the reset signal Reset, the source terminal is connected to the reset voltage terminal Vrst, and the drain terminal is connected to the node FD. The control terminal of the transmission gate switch transistor TX is configured to receive the transmission signal TX, the source terminal is connected to the PD, and the drain terminal is connected to the FD. The control terminal of the source follower transistor Tsf is connected to the node FD, and the source terminal is connected to the power supply terminal Vdd and the drain terminal is connected to the source terminal of the selection switch transistor. The control terminal of the selection switch transistor Tsel is configured to receive the selection signal Select, and the drain terminal is connected to the external column output bus. The detection circuit in FIG. 6 can reduce the crosstalk of the sensors in the same row and improve the detection accuracy of the sensors. Details are not repeated here.

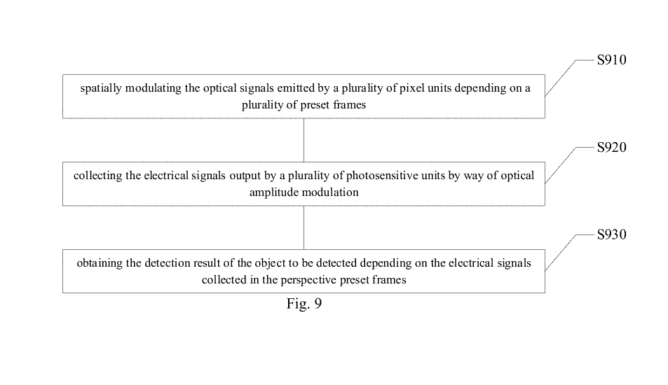

In addition, in the present exemplary embodiment, there is also provided an image collection method which is applied to the array substrate described in the above embodiments. Referring to FIG. 9, the image collection method may comprise:

step 5910 of spatially modulating the optical signals emitted by the plurality of pixel units depending on a plurality of preset frames;

step 5920 of collecting the electrical signals output by the plurality of photosensitive units by way of optical amplitude modulation; and

step 5930 of obtaining the detection result of the object to be detected depending on the electrical signals collected in the perspective preset frames.

Further, in the present exemplary embodiment, spatially modulating the optical signal may comprise:

spatially modulating the optical signals by the plurality of pixel units in a manner of being alternately bright and dark.

It should be noted that although various steps of the method in the present disclosure are described in a specific order in the drawings, this does not require or imply that these steps must be performed in this particular order, or all the steps shown must be performed in order to achieve the desired result. Additionally or alternatively, some steps may be omitted, multiple steps may be combined into one step, and/or one step may be broken down into multiple steps for execution.

Further, another exemplary embodiment of the present disclosure provides a display device, which may comprise any of the array substrates according to the foregoing embodiments. Since the illumination system in the present exemplary embodiment employs the above-described array substrate, it has at least all the advantages corresponding to the array substrate. In this exemplary embodiment, the display device may be any product or component having a display function such as an OLED panel, a mobile phone, a tablet computer, a television, a monitor, a notebook computer, a digital camera, etc., which is not specifically limited in the present disclosure.

In the array substrate and the display device according to an embodiment of the present disclosure, a PMOLED pixel structure is adopted, a plurality of photosensitive units are disposed at the gaps of the pixel units, and light signals emitted from the pixel units and reflected by the object to be detected are received by the photosensitive units. On the one hand, using the PMOLED pixel structure, a plurality of photosensitive units are disposed at the gaps between the pixel cells. Since the PMOLED pixel structure does not need to provide pixel circuits on the array substrate, sufficient space may be provided for the photosensitive units and photosensitive unit detection circuits. On the other hand, the light signals emitted from the pixel unit and reflected by the object to be detected are received by the photosensitive units. Since the driving mode of the PMOLED is progressive driving mode, the signal interference caused by luminance of other lines of pixels illuminating onto the photosensitive elements can be relieved, the ambient light interference is reduced, the signal-to-noise ratio is improved, and thus the relatively weak light signals can be collected.

By considering the specification and practicing contents disclosed herein, those skilled in the art will readily envisage other embodiments of the present disclosure. This application is intended to cover any variations, uses, or adaptations of the present disclosure which follow the general principles of the present disclosure and comprise any common knowledge or conventional techniques in this technical field not disclosed in this disclosure. The description and examples are to be considered exemplary only, and the true scope and spirit of the disclosure are indicated by the appended claims.

It should be understood that the present disclosure is not limited to the precise structure that has been described above and shown in the drawings, and may have various modifications and changes without departing from the scope thereof. The scope of the present disclosure is limited only by the appended claims.

1. An array substrate comprising:
a base substrate;
a plurality of first electrodes disposed on the base substrate;
a plurality of second electrodes disposed above the plurality of first electrodes, wherein orthographic projections of the plurality of the second electrodes on the base substrate and orthographic projections of the plurality of the first electrodes on the base substrate are arranged to intersect each other;
a plurality of pixel units located in overlapping areas of the orthographic projections of the plurality of the second electrodes on the base substrate and the orthographic projections of the plurality of the first electrodes on the base substrate, respectively; and
a plurality of photosensitive units disposed at gaps between adjacent two of the plurality of the pixel units, respectively.

2. The array substrate according to claim 1, wherein the plurality of the photosensitive units are located between the base substrate and the plurality of the first electrodes.

3. The array substrate according to claim 1, wherein the plurality of the photosensitive units are located in areas not covered by the first electrodes and not covered by the second electrodes.

4. The array substrate according to claim 1, wherein the plurality of the pixel units are OLED pixel units.

5. The array substrate according to claim 1, further comprising:
a photosensitive detection circuit disposed on the base substrate and configured to collect electrical signals output by the plurality of the photosensitive units.

6. The array substrate according to claim 5, wherein the photosensitive detection circuit comprises an active detection circuit.

7. The array substrate according to claim 1, further comprising:
a driving unit configured to drive the plurality of the pixel units by way of progressive scanning.

8. The array substrate according to claim 1, wherein the plurality of the photosensitive units are PIN photosensitive elements or PN junction photosensitive elements.

9. An image collection method, which is applied to the array substrate according to claim 1, comprising:
spatially modulating optical signals emitted by the plurality of the pixel units depending on a plurality of frames;
collecting electrical signals output by the plurality of the photosensitive units by way of optical amplitude modulation; and
obtaining detection result of an object to be detected depending on the electrical signals collected in the perspective preset frames.

10. The image collection method according to claim 9, wherein the spatially modulating optical signals comprises:
spatially modulating the optical signals by the plurality of the pixel units in a manner of being alternately bright and dark.

11. A display device comprising the array substrate according to claim 1.
